(19) United States
(12) Patent Application Publication
(10) Pub. No.: US 2025/0264503 A1
(43) Pub. Date: Aug. 21, 2025

(54) OPTICAL VOLTAGE PROBE

(71) Applicant: SEIKOH GIKEN Co., Ltd., Matsudo-shi (JP)

(72) Inventor: Ryuji OSAWA, Matsudo-shi (JP)

(21) Appl. No.: 19/046,514

(22) Filed: Feb. 6, 2025

(30) Foreign Application Priority Data
Feb. 16, 2024 (JP) 2024-021785

(51) Int. Cl. G01R 15/24; G01R 19/00; G02F 1/035

(52) U.S. Cl. CPC G01R 15/241; G01R 19/0084; G02F 1/035; G02F 2202/20

(57) ABSTRACT

An optical modulator configured to modulate an intensity of an incident light depending on a voltage between first and second electrode pads; first and second contact terminals that are configured to be in contact with the measurement point; a first electric line connecting the first contact terminal with the first electrode pad; and a second electric line connecting the second contact terminal with the second electrode pad are provided, the first and second contact terminals or the first and second electric lines are crossed with each other at least one time in a non-contact manner, and electromotive forces in opposite directions are induced between the first and second contact terminals or between the first and second electric lines at portions before and after a crossing portion when a magnetic field penetrating between the first and second contact terminals or between the first and second electric lines varies.

### CROSS-REFERENCE TO RELATED APPLICATIONS

This patent specification is based on Japanese patent application, No. 2024-021785 filed on Feb. 16, 2024 in the Japan Patent Office, the entire contents of which are incorporated by reference herein.

### TECHNICAL FIELD

The present invention relates to an optical voltage probe that applies a voltage signal obtained from contact terminals to an optical modulator, converts the voltage signal into an optical modulation signal, and outputs the optical modulation signal through an optical fiber.

### BACKGROUND OF THE INVENTION

In recent years, various control devices using a high speed CPU or the like have been developed and various tests such as ESD (Electrostatic Discharge) test and noise resistance test are performed on electric circuits and electric components by applying various electric loads on them after they are charged as a malfunction preventive countermeasure. The evaluation criteria for the above described tests primarily focus on verifying malfunction or destruction. Thus, it is required to accurately measure input/output signals of the electric components installed on electric circuit boards and electrical signals transmitted through wirings.

As for a general method for measuring the electric signals of the electric components and the wirings, the electric signals of the measurement point are transferred to a measuring instrument such as an oscilloscope by using an electric probe having contact terminals and voltage waveforms or the like of the transferred electric signals are measured. However, when a ground level of the measurement point is different from that of the measuring instrument or when the voltage signal between ungrounded two points is measured, it is difficult to measure the voltage waveforms correctly because of the influence of the mixture of signals from the ground and the capacity of the electric probe, for example. In particular, the above described influence of the ground and the capacity is large in a high frequency region. Furthermore, an input impedance and an output impedance are not 500 in many integrated circuits such as IC and LSI. Therefore, when the noise voltage is measured by using the electric probe having a low input impedance, current flows to the electric probe side and the electric signals and the noise voltage to be measured are lowered.

As for the means for solving the above described problem, a measuring instrument using an optical voltage probe has been developed where the voltage signal is converted into an optical signal and the optical signal is transferred to the measuring instrument through an optical fiber. In the above described method, a capacity component of the probe is extremely low and the input impedance is extremely high. Thus, the original electrical signals and noise voltage are converted into optical signal without degradation. Furthermore, since the optical signals are transmitted through the optical fiber, the measurement point and the measuring instrument are electrically separated from each other completely. In the optical voltage probe, even high frequency component can be measured, the influence of the ground can be eliminated and the intrusion of the electric signal noise generated midway can be prevented.

Examples of the above described conventional measuring instruments are described in Patent documents 1, 2 and 3.

Patent document 1 describes the optical voltage probe using a bulk type optical modulator. The voltage signal of the contact terminals is applied on a crystal having an electrooptic effect to change the polarization state of an incident light and convert the incident light into a light intensity modulated light through an analyzer and transmit the light intensity modulated light to an O/E converter through the optical fiber.

Patent document 2 describes the optical voltage probe having a waveguide type optical modulator. This obtains an optical intensity modulation signal by applying the voltage signal of the contact terminals between two modulation electrodes of a branch interference type optical modulator formed on a lithium niobate crystal substrate. A device having a light source and an O/E converter is connected with the optical voltage probe through the optical fiber.

Patent document 3 describes the configuration where a package of the optical voltage probe is covered with conductive materials such as a metal or radio wave absorbing materials such as a ferrite.

### PRIOR ART DOCUMENT

### Patent Documents

[Patent document 1] Japanese Unexamined Patent Application Publication No. S63-196863
[Patent document 2] Japanese Unexamined Patent Application Publication No. H8-35998
[Patent document 3] Japanese Unexamined Patent Application Publication No. 2021-165666

### SUMMARY OF THE INVENTION

As described above, in the conventional optical voltage probe, the influence of the ground can be eliminated and the intrusion of the electric signal noise generated midway of the wirings to the measuring instrument can be prevented. Furthermore, in the optical voltage probe of Patent Document 3, the package is covered with the metal or the radio wave absorbing materials to eliminate the influence of the radio wave noise which directly reaches the modulation electrodes through space around the optical voltage probe using the wirings extended from the contact terminals to the modulation electrodes as an antenna.

However, in the ESD test, the voltage of several kV is generated on the charged plate mounted with the electric circuit boards and the current of several amperes may flow when the charged plate is grounded and discharged. In the conventional optical voltage probe, even when the cover for shielding the above described radio wave is provided, the discharge noise is directly captured by the optical voltage probe. Thus, the input/output signals of the electrical components and the signals traveling through the wirings may not be accurately measured. Through experiments conducted by the inventors, it is revealed that the above described phenomenon is caused because the discharged current generates large varying magnetic field in the surrounding area and induces electromotive force in the wirings extended from the contact terminals to the modulation electrodes. Furthermore, the above described magnetic field is so strong that it cannot be completely eliminated even when the optical voltage probe is covered with simple magnetic materials.

The present invention aims for providing an optical voltage probe capable of solving the above described problem, reducing the influence of the varying magnetic field in the surrounding area and correctly measuring the voltage signal of the measurement point.

For solving the above described problem, the first viewpoint of the optical voltage probe of the present invention is an optical voltage probe for measuring a voltage signal at a measurement point, the optical voltage probe including: an optical modulator having a first electrode pad and a second electrode pad, the optical modulator being configured to modulate an intensity of an incident light depending on a voltage between the first electrode pad and the second electrode pad and output the modulated incident light; an input optical fiber and an output optical fiber that are connected with the optical modulator; a first contact terminal and a second contact terminal that are configured to be in contact with the measurement point; a first electric line connecting the first contact terminal with the first electrode pad; a second electric line connecting the second contact terminal with the second electrode pad; and a package that houses the optical modulator, at least a part of the first electric line, at least a part of the second electric line, a part of the input optical fiber and a part of the output optical fiber, wherein the voltage signal induced between the first electrode pad and the second electrode pad via the first contact terminal and the second contact terminal is converted into an optical intensity modulation signal by the optical modulator and the optical intensity modulation signal is outputted through the output optical fiber, the first contact terminal and the second contact terminal or the first electric line and the second electric line include a crossing portion so that the first contact terminal and the second contact terminal or the first electric line and the second electric line are crossed with each other at the crossing portion in a non-contact manner, and when a magnetic field penetrating between the first contact terminal and the second contact terminal or between the first electric line and the second electric line varies, electromotive forces in opposite directions are induced between the first contact terminal and the second contact terminal or between the first electric line and the second electric line at portions before and after the crossing portion by the magnetic field which varies.

In conventional optical voltage probes, as mentioned above, when large varying magnetic field is generated in the surrounding area by the discharged current or the like and the magnetic field penetrates between the first and second contact terminals or between the first and second electrical lines, the electromotive force is induced between the first and second contact terminals or the first and second electric lines by the varying magnetic field. The induced electromotive force is superimposed on the voltage signal between the first and second contact terminals and applied between the first and second electrode pads. Consequently, the accurate measurement of the voltage signal at the measurement point is interrupted. On the other hand, in the optical voltage probe of the present invention, as mentioned above, the first contact terminal and the second contact terminal or the first electric line and the second electric line are crossed with each other in a non-contact manner. Thus, the electromotive forces in opposite directions are induced between the first contact terminal and the second contact terminal or between the first electric line and the second electric line at portions before and after the crossing portion. Therefore, the induced electromotive forces are canceled each other and the influence of the varying magnetic field can be reduced. Consequently, the effect of the varying magnetic field in the surrounding area is reduced and the voltage signal of the measurement point can be measured more accurately.

The optical voltage probe of the present invention can be effectively used not only in the ESD test mentioned above but also in various measurement environments where the varying magnetic field exists. For example, the optical voltage probe can be used for the measurement near a power supply device or a driving device where significant varying magnetic field is generated and the measurement of the electrical component within an electrical circuit that partially contains a circuit generating the varying magnetic field.

Although the measurement in the optical voltage probe is made by bringing the contact terminals into contact with the measurement point on the circuit board or the like, the contact terminals may be integrated into the optical voltage probe or may be configured to be detachable from the package so that the contact terminals can be selected depending on the purpose.

In the second viewpoint of the present invention, the optical voltage probe of the first viewpoint is characterized in that the magnetic field is generated by an electric load in a test environment where the electric load is applied to an electric circuit or an electric component, and the measurement point is located in the electric circuit or the electric component. In this viewpoint of the present invention, the optical voltage probe is used in the test environment where the electric load is applied, where the effectiveness is confirmed by the inventors.

In the third viewpoint of the present invention, the optical voltage probe of the first viewpoint is characterized in that the first contact terminal and the second contact terminal or the first electric line and the second electric line include a plurality of crossing portions, each of the plurality of crossing portions being the crossing portion. The induced electromotive force is proportional to the magnitude of the magnetic flux within the area enclosed by the electrical lines such as the first and second contact terminals and the first and second electric lines. When the magnetic flux density is constant, the induced electromotive force is proportional to the above described area. In order to reduce the influence of the varying magnetic field by cancelling the induced electromotive forces in the portions before and after the crossing portion, the areas enclosed by the electrical lines before and after the crossing portion must be as equal as possible. In this case, rather than providing just one crossing portion and trying to make the areas enclosed by the electrical lines equal before and after the crossing portion, it is easier to provide a plurality of crossing portions to make the areas enclosed by the electrical lines smaller for cancelling the induced electromotive force at a plurality of areas.

In the fourth viewpoint of the present invention, the optical voltage probe of the first viewpoint is characterized in that the first electric line and the second electric line are twisted together in the non-contact manner. As described above, since the first electric line and the second electric line are twisted together in the non-contact manner, the area of the region enclosed by the first electric line and the second electric line through which the varying magnetic field passes can be reduced and the induced electromotive force can be canceled in a number of regions.

In the fifth viewpoint of the present invention, the optical voltage probe of the first viewpoint is characterized in that the first electric line and the second electric line include the crossing portion, a first area of a first region enclosed by a first straight line connecting terminals of the first electric line and the second electric line, the first electric line, the second electric line and the crossing portion or a second area of a second region enclosed by the crossing portion, the first electric line, the second electric line and a second straight line connecting rear ends of the first electric line and the second electric line is adjustable.

In the present invention, for canceling the induced electromotive force generated in the portions before and after the crossing portion, the areas enclosed by the electrical lines before and after the crossing portion must be equal. In this viewpoint of the present invention, the first electric line and the second electric line are configured to cross each other so that at least one of the areas enclosed by the first and second electric lines before and after the crossing portion is made adjustable. Consequently, for example, the induced electromotive force generated in the portions of the first and second electrical lines can be canceled by making the areas enclosed by the first and second electrical lines equal before and after the crossing portion. In addition, when the induced electromotive force is generated in the first and second contact terminals, it is possible to adjust the induced electromotive force to cancel the induced electromotive force generated in the first and second contact terminals by the induced electromotive force generated in the first and second electrical lines.

In the sixth viewpoint of the present invention, the present invention is characterized in that the first electric line and the second electric line includes the crossing portion, and lengths of the first contact terminal and the second contact terminal are adjustable so that an area of a region enclosed by a straight line connecting terminals of the first contact terminal and the second contact terminal, the first contact terminal, the second contact terminal, the first electric line and the second electric line which are connected respectively with the first contact terminal and the second contact terminal, and the crossing portion is adjustable.

In this viewpoint of the present invention, the first electric line and the second electric line are configured to cross each other and the lengths of the first contact terminal and the second contact terminal are made adjustable. Thus, the area enclosed by the first contact terminal and the second contact terminal is made adjustable. Consequently, the total area enclosed by the first and second electric lines and the first and second contact terminals before the crossing portion is made adjustable. By the above described adjustment, when the above described total area can be made equal to the area enclosed by the first and second electrical lines after the crossing portion, the induced electromotive forces generated in the portions before and after the crossing portion can be canceled.

In the seventh viewpoint of the present invention, the optical voltage probe of the first to sixth viewpoints is characterized in that the optical modulator is a branch interference type optical modulator using an optical waveguide formed on a lithium niobate crystal substrate. This viewpoint of the present invention uses the branch interference type optical modulator achieved by the optical waveguide formed on the lithium niobate crystal substrate although it has been conventionally used as the optical modulator. The branch interference type optical modulator is basically composed of an input optical waveguide extended from a light incident side, two phase shift waveguides extended from the input optical waveguide and branched into two, an output optical waveguide at which the two phase shift optical waveguides are joined and connected to a light emission side, and modulation electrodes arranged in parallel with the two phase shift waveguides. The voltage signal is applied to the phase shift optical waveguides via the modulation electrodes, a refractive index of the phase shift optical waveguides is changed, and the light passing through the two phase shift optical waveguides are joined and interfered with each other. Thus, the optical intensity is modulated. Since a small, high efficient and broadband optical modulator can be obtained, it is suitable for the optical voltage probe of the present invention.

In the present invention, a so-called split electrode (segmented electrode) formed by a plurality of electrodes which are divided in a longitudinal direction and capacitively coupled with each other is used as the modulation electrode. The split electrode formed by dividing one modulation electrode into a plurality of capacitively coupled electrodes is an efficient means for improving the trade-off relation between the length of the modulation electrodes and the electric capacity, the trade-off relation relating to the modulation efficiency and the modulation bandwidth. The high efficient and broadband optical modulator can be obtained by using the split electrode.

In the eighth viewpoint of the present invention, the optical voltage probe of the first to sixth viewpoints is characterized in that the optical modulator is a branch interference type optical modulator using an optical waveguide formed on a lithium niobate crystal substrate, the incident light is reflected inside the optical modulator to change a direction of the incident light, and the input optical fiber and the output optical fiber are formed by one input/output optical fiber. The reflection type optical modulator of this viewpoint of the present invention has the configuration that the incident light is reflected in the phase shift optical waveguide and returned to the optical waveguide of the incident side. When the above described configuration of the reflection type optical modulator is used, the length through which the light is transmitted is twice the length compared to the case where a transmission-type optical modulator having the electrode of the same length is used. Thus, the optical modulator can be more efficient, more broadband and smaller. Furthermore, since the number of the optical fiber connected to the optical modulator is one, handling is facilitated.

As described above, the present invention provides an optical voltage probe capable of reducing the influence of surrounding varying magnetic field and measuring the voltage signal more accurately at the measurement point.

### BRIEF DESCRIPTION OF DRAWINGS

FIGS. 1A and 1B are configuration diagrams schematically showing the configuration of the optical voltage probe concerning the first embodiment. FIG. 1A is a plan view of the transmission-type and FIG. 1B shows a side view of the transmission-type.

FIG. 2 is a block diagram of a measurement system using the optical voltage probe concerning the first embodiment.

FIGS. 3A and 3B are diagrams schematically showing an example of the configuration of a reflection type optical modulator included in the optical voltage probe concerning the first embodiment. FIG. 3A is a plan view and FIG. 3B is an A-A cross-sectional view.

FIG. 4 is a plan view of the transmission-type schematically showing a configuration of an optical voltage probe concerning the second embodiment.

FIG. 5 is a plan view of the transmission-type schematically showing a configuration of an optical voltage probe concerning the third embodiment.

FIG. 6 is a plan view of the transmission-type schematically showing a configuration of an optical voltage probe concerning the fourth embodiment.

### DETAILED DESCRIPTION OF THE INVENTION

Hereafter, the optical voltage probe of the present invention will be explained in detail using the embodiments with reference to the drawings. Note that the same reference numerals are added to the same elements in the explanation of the drawings and the repeated explanation will be omitted.

### First Embodiment

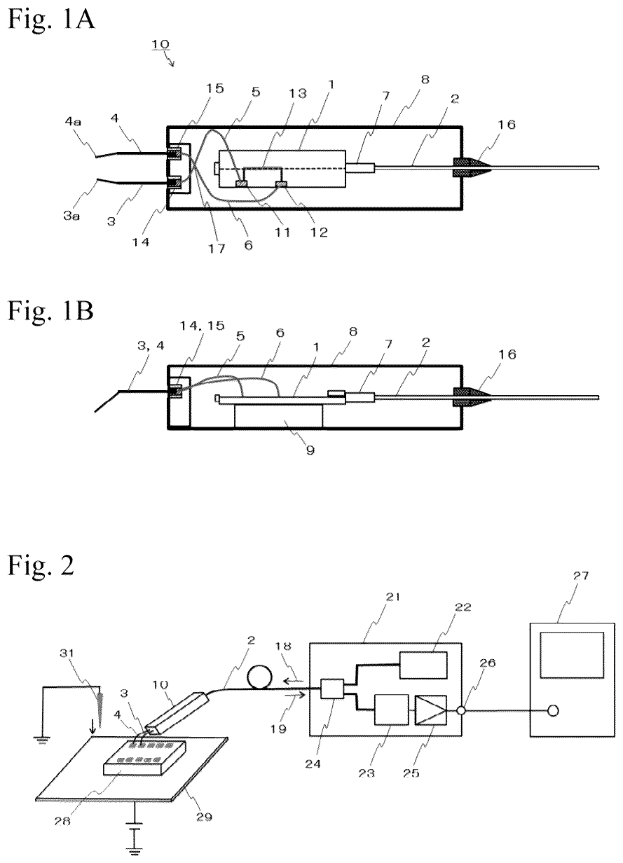

FIGS. 1A and 1B are configuration diagrams schematically showing the configuration of the optical voltage probe concerning the first embodiment. FIG. 1A is a plan view of the transmission-type and FIG. 1B shows a side view of the transmission-type.

In FIGS. 1A and 1B, an optical voltage probe 10 of the first embodiment includes: an optical modulator 1 having modulation electrodes 13 which include an electrode pad 11 (first electrode pad) and an electrode pad 12 (second electrode pad); and an input optical fiber and an output optical fiber connected with the optical modulator 1. The optical modulator 1 is configured to modulate an intensity of an incident light depending on a voltage between the first electrode pad 11 and the second electrode pad 12 and output the modulated incident light. The optical voltage probe 10 further includes: a contact terminal 3 (first contact terminal); a contact terminal 4 (second contact terminal) that are configured to be in contact with the measurement point; a wiring 5 (first electric line) connecting the contact terminal 3 with the electrode pad 11; and a wiring 6 (second electric line) connecting the contact terminal 4 with the electrode pad 12. Furthermore, the wiring 5 and the wiring 6 are crossed with each other in a non-contact manner at a crossing portion 17. In the present embodiment, the optical modulator 1 is a reflection type optical modulator which reflects the incident light inside the optical modulator 1 to change a direction of the incident light. The input optical fiber inputted to the optical modulator 1 and the output optical fiber outputted from the optical modulator 1 are constructed as a single input/output optical fiber 2. A terminal of the input/output optical fiber 2 is inserted and fixed in a ferrule 7 so that the end surface of the input/output optical fiber 2 is adhered and fixed with the end surface of the input/output terminal of the optical modulator 1.

The optical modulator 1, the wirings 5, 6 and a part of the input/output optical fiber 2 is housed inside a package 8. The contact terminals 3, 4 are configured to be detachable by making the contact terminals 3, 4 contact respectively with metal cylindrical portions of contact terminal attachment portions 14, 15 which are fixed to the package 8. The metal cylindrical portions are fixed inside a cylindrical insulators and the insulators are fixed to the package 8. When performing the measurement, the contact terminal 3 is inserted into the contact terminal attachment portion 14 and the contact terminal 4 is inserted into the contact terminal attachment portion 15. The wirings 5, 6 are connected respectively with the metal cylindrical portions.

The package 8 is formed in a rectangular parallelepiped shape and constructed from a metal plate such as aluminum for shielding an external electric field. The optical modulator 1 is fixed to a seat 9 which is fixed to the package 8. The input/output optical fiber 2 is fixed to the package 8 by a fixing member 16 made of rubber.

Next, the measurement system using the optical voltage probe 10 of the present embodiment will be explained.

FIG. 2 is a block diagram of the measurement system using the optical voltage probe concerning the first embodiment. As shown in FIG. 2, an incident light 18 is transmitted from an optical transmission/reception unit 21 to the optical voltage probe 10 through the input/output optical fiber 2. An optical intensity modulation signal 19 outputted from the optical modulator 1 is inputted to the optical transmission/reception unit 21 through the same input/output optical fiber 2.

The optical transmission/reception unit 21 includes a light source 22 such as a semiconductor laser, an O/E (Optical/Electrical) converter 23, a transmission/reception separator 24 for separating the incident light 18 from the optical intensity modulation signal 19, and an amplifier 25. An emission light emitted from the light source 22 is coupled into the input/output optical fiber 2 through the transmission/reception separator 24. The optical intensity modulation signal 19 returned from the input/output optical fiber 2 is inputted to the O/E converter 23 through the transmission/reception separator 24. The optical intensity modulation signal 19 is converted into the electric signal in the O/E converter 23, and the electric signal is amplified by the amplifier 25 and output to an output terminal 26. The outputted electric signal is inputted to a measuring instrument 27 such as an oscilloscope. The transmission/reception separator 24 can be formed by one of an optical circulator, an optical fiber splitter and a semi-transparent mirror.

FIG. 2 shows the case where the voltage signal applied between two terminals of an electric component 28 such as an IC installed on a charged plate 29 as the measurement point in the ESD test. The contact terminals 3 and 4 of the optical voltage probe 10 are brought into contact with two terminals of the electric component 28 to be measured. As shown in FIGS. 1A and 1B, the voltage signal inputted through the contact terminals 3, 4 is led to the modulation electrode 13 through the wirings 5, 6 and the electrode pads 11, 12. The voltage signal is converted into the optical intensity modulation signal 19 by the optical modulator 1. The optical intensity modulation signal 19 is converted into the electric signal in the optical transmission/reception unit 21. The voltage waveform of the voltage signal is observed by the measuring instrument 27, for example. Thus, the waveform of the voltage signal generated between the two terminals of the electric component 28 can be recognized.

In the ESD test, the voltage is applied on the charged plate 29 to charge the charged plate 29, a ground needle 31 is brought into contact with the charged plate 29 and the voltage signal of the measurement terminal is measured to examine malfunction and breakage of the electric component 28 when the charged plate is discharged. In the above described ESD test, high voltage of several kV is generated in the charged plate 29. When the charged plate 29 is discharged, the current of several amperes may flow and large varying magnetic field is generated in the surrounding area. In the conventional optical voltage probe, when the above described magnetic field penetrates between the contact terminals 3 and 4 or between the wirings 5 and 6, the electromotive force is induced by the varying magnetic field and the induced electromotive force is superimposed on the voltage signal between the contact terminals 3 and 4 and applied between the electrode pads 11 and 12. Thus, accurate measurement of the voltage signal is interrupted at the measurement point.

On the other hand, in the optical voltage probe of the present embodiment, as shown in FIGS. 1A and 1B, the wiring 5 and the wiring 6 are crossed with each other in a non-contact manner. Thus, the electromotive forces in opposite directions are induced between the wirings 5 and 6 at the portions before and after the crossing portion 17. Consequently, the induced electromotive forces are canceled with each other and the influence of the varying magnetic field can be reduced. Furthermore, in the present embodiment, the area of the region enclosed by a straight line connecting terminals 3a and 4a of the contact terminals 3, 4, the contact terminals 3, 4, the wirings 5, 6 connected through the contact terminal attachment portions 14, 15 and the crossing portion 17 is set to be approximately equal to the area of the region enclosed by the crossing portion 17, the wirings 5, 6 and the electrode pads 11, 12 which are located rear end side. The magnitude of the induced electromotive force is proportional to the above described area of the region when magnetic flux density is constant. Thus, the influence of the varying magnetic field can be canceled by making the areas of the portions equal before and after the crossing portion. Consequently, the influence of the magnetic field in the surrounding area is reduced and the voltage signal of the measurement point can be measured more accurately.

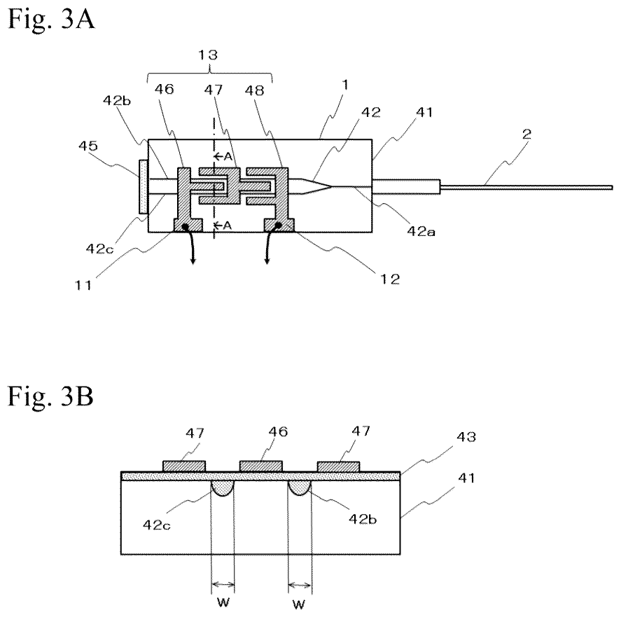

FIGS. 3A and 3B are diagrams schematically showing an example of the configuration of the reflection type optical modulator 1 included in the optical voltage probe 10 of the present embodiment. FIG. 3A is a plan view and FIG. 3B is an A-A cross-sectional view.

In FIGS. 3A and 3B, the optical modulator 1 is composed of: a substrate 41 formed by cutting (X cutting) a lithium niobate (LiNbO₃) crystal which is a crystal having an electrooptic effect; a branch interference type optical waveguide 42 formed on an upper surface side of the substrate 41 by Ti diffusion; a buffer layer 43 coated on an upper surface side of the substrate 41; a modulation electrode 13 coated on the buffer layer 43; and a light reflecting portion 45 provided on one of end portions of the substrate 41. The modulation electrode 13 is a two-layered film of chrome (Cr) and aurum (Au) formed by sputtering or the like.

The branch interference type optical waveguide 42 is composed of: an input/output optical waveguide 42a extending toward the direction from which the input (incident) light is inputted; and two phase shift optical waveguides 42b, 42c extended from the input/output optical waveguide 42a and branched into two. In the input/output optical waveguide 42a and the phase-shift optical waveguides 42b, 42c, the widths W, which are vertical to the direction of extending the waveguides 42a, 42b and 42c, are within the range of 5 to 12 μm and are equal to each other. In addition, the lengths of the phase shift optical waveguides 42b, 42c in the extending direction are within the range of 10 to 30 mm and are approximately equal to each other. The phase shift optical waveguides 42b, 42c are separated from each other and extended in parallel to each other so that the center parts of them are separated by a predetermined distance within the range of 15 to 50 μm in the width direction. The buffer layer 43 is provided for the purpose of preventing a part of the light propagating through the optical waveguides 42 from being absorbed by the modulation electrode 13. The buffer layer 43 is mainly made of silica (SiO₂) film or the like and the thickness of the buffer layer 43 is approximately 0.1 to 1.0 μm.

In the optical modulator 1, the modulation electrode 13 is composed of split electrodes formed by three electrodes 46, 47, 48 which are divided from each other in a longitudinal direction of the branch interference type optical waveguide 42 and capacitively coupled with each other. Between the electrode pads 11 and 12, the electrodes 46, 47 and the electrodes 47, 48 are capacitively coupled with each other and arranged in series.

The input/output terminal of the input/output optical fiber 2 is coupled with the light input/output end of the input/output optical waveguide 42a of the substrate 41. The light reflecting portion 45 reflects the light incident from the input/output optical waveguide 42a and propagated through the phase shift optical waveguides 42b, 42c to return the light and make the light propagate from the phase shift optical waveguides 42b, 42c to the input/output optical waveguide 42a. When the voltage is applied between the electrode pads 11 and 12, an electric field is applied to the two phase shift optical waveguides 42b, 42c (i.e., between the electrodes 46 and 47 and between the phase-shift optical waveguides 42b, 42c) in an opposite direction to each other. Consequently, the refractive index change occurs in the phase shift optical waveguides 42b, 42c in an opposite direction to each other. Thus, a phase shift having polarity opposite to each other is made in the light passing through the phase shift optical waveguides 42b, 42c. The intensity change occurs when the lights are joined since the lights are interfered with each other. Consequently, the optical intensity modulation signal having the light intensity change depending on the voltage applied between the electrode pads 11 and 12 can be obtained.

The ESD test was performed using the optical voltage probe of the present embodiment and it was confirmed that the voltage signal of the measurement point could be accurately measured without being influenced by the magnetic field generated by the discharge.

### Second Embodiment

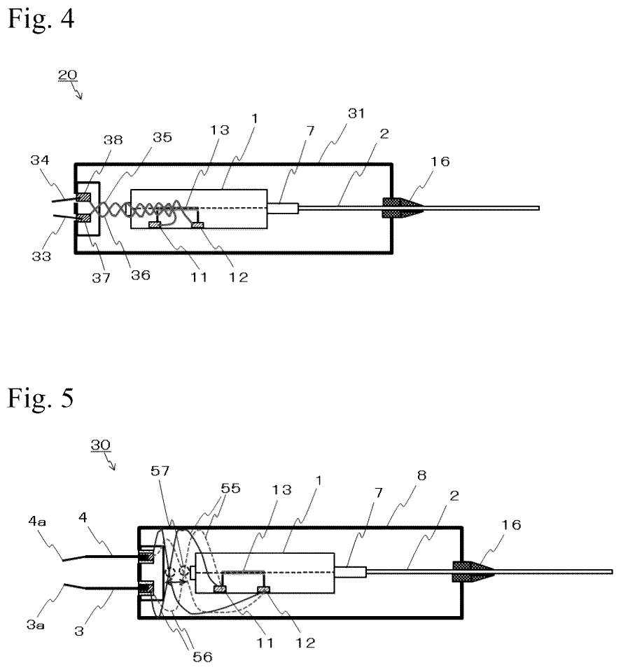

FIG. 4 is a plan view of the transmission-type schematically showing a configuration of an optical voltage probe concerning the second embodiment. As shown in FIG. 4, in an optical voltage probe 20 of the second embodiment, the optical modulator 1 similar to the first embodiment is installed and fixed inside a package 31. In the second embodiment, a contact terminal 33 is connected to a wiring 35 via a terminal plate 37 while a contact terminal 34 is connected to a wiring 36 via a terminal plate 38. Furthermore, the wiring 35 and the wiring 36 are twisted together in a non-contact manner and are connected to the electrode pads 11 and 12 respectively. As describe above, the wirings 35 and 36 are twisted together. Thus, the area of the region enclosed by the above described wirings through which the varying magnetic field pass can be reduced and the induced electromotive force can be canceled in a number of regions. Consequently, the influence of the magnetic field in the surrounding area can be reduced.

### Third Embodiment

FIG. 5 is a plan view of the transmission-type schematically showing a configuration of an optical voltage probe concerning the third embodiment. An optical voltage probe 30 of the third embodiment is same as the first embodiment except for the first and second electric lines. In the third embodiment, a wiring 55 (first electric line) and a wiring 56 (second electric line) are configured to cross with each other in a non-contact manner at a crossing portion 57. The position of the crossing portion 57 is configured to be movable frontward and rearward (i.e., leftward and rightward in FIG. 5) of the crossing portion. The solid lines in FIG. 5 show the case where the crossing portion 57 of the wirings 55, 56 is located at the contact terminals 3, 4 side while the broken lines in FIG. 5 show the case where the crossing portion 57 is located at the electrode pads 11, 12 side.

As shown in FIG. 5, the area enclosed by the wirings 55, 56 shown in the solid lines is smaller than the area enclosed by the wirings 55, 56 shown in the broken lines at the front (i.e., left) of the crossing portion. On the contrary, the area shown in the solid lines is larger than the area shown in the broken lines at the rear (i.e., right) of the crossing portion. As described above, the area of the region enclosed by the straight line connecting the terminals of the wirings 55, 56, the wirings 55, 56 and the crossing portion 57 and the area of the region enclosed by the crossing portion 57, the wirings 55, 56 and the straight line connecting rear ends of the wirings 55, 56 are adjustable by adjusting the position of the crossing portion 57 frontward and rearward. When the area enclosed by the contact terminals 3, 4 and the wirings 55, 56 before the crossing portion 57 is adjusted to be equal to the area enclosed by the wirings 55, 56 after the crossing portion 57 by the above described adjustment, the induced electromotive forces generated before and after the crossing portion 57 can be canceled each other. The above described adjustment can be made by various methods. For example, the lid of the package 8 is configured to be removable for the adjustment. Alternatively, a tip of an adjustment rod is fixed to the crossing portion 57 and the adjustment rod is inserted from outside the package 8 and configured to be movable.

### Fourth Embodiment

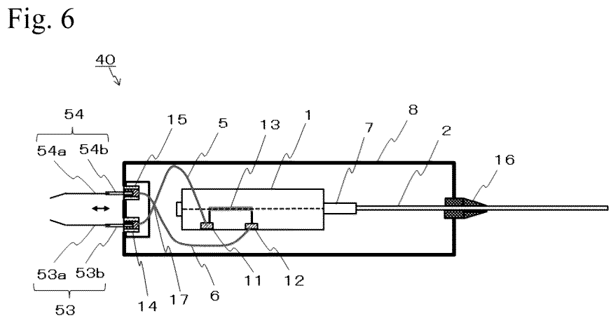

FIG. 6 is a plan view of the transmission-type schematically showing a configuration of an optical voltage probe concerning the fourth embodiment. An optical voltage probe 40 of the fourth embodiment is same as the first embodiment except for the first and second contact terminals. In the fourth embodiment, lengths of a contact terminal 53 (first contact terminal) and a contact terminal 54 (second contact terminal) are adjustable. Specifically, the contact terminals 53, 54 are formed respectively by terminal needles 53a, 54a and metal tubes 53b, 54b into which the terminal needles 53a, 54a can be inserted while contacting with each other. By adjusting the depth where the terminal needles 53a, 54a are inserted into the metal tubes 53b, 54b, the lengths of the contact terminals 53, 54 (i.e., lengths from the terminals of the terminal needles 53a, 54a to the rear ends of the metal tubes 53b, 54b) can be adjusted.

Consequently, the total area enclosed by the wirings 5, 6 and the contact terminals 53, 54 before the crossing portion 17 can be adjusted. When the above described total area can be made equal to the area enclosed by the wirings 5, 6 and the straight line connecting the electrode pads 11 and 12 after the crossing portion 17, the induced electromotive forces generated in the portions before and after the crossing portion 17 can be canceled each other.

It goes without saying that the present invention is not limited to the above described embodiments and the present invention can be variously modified in accordance with various purposes. For example, it is also possible to provide the crossing portion in the contact terminal in addition to the wirings for canceling the induced electromotive force. The type of the optical modulator to be used is not limited to the reflection type. A transmission-type optical modulator can be also used. It is not necessary to form the modulation electrode by the sprit electrode. The shape, structure and the like of the contact terminal and the contact terminal attachment portion can be selected according to the purpose. In addition, the material, shape and structure of the package can be arbitrarily selected. For example, in addition to the rectangular parallelepiped shape of the above described embodiment, a cylindrical shape or the like can be also used.

### DESCRIPTION OF THE REFERENCE NUMERALS

1: optical modulator; 2: input/output optical fiber; 3, 4, 33, 34, 53, 54: contact terminal; 3a, 4a: terminal; 5, 6, 35, 36, 55, 56: wiring; 7: ferrule; 8, 31: package; 9: seat; 10, 30, 20, 30, 40: optical voltage probe; 11, 12: electrode pad; 13: modulation electrode; 14, 15: contact terminal attachment portion; 16: fixing member; 17, 57: crossing portion; 18: incident light; 19: optical intensity modulation signal; 21: optical transmission/reception unit; 22: light source; 23: O/E converter; 24: transmission/reception separator; 25: amplifier; 26: output terminal; 27: measuring instrument; 28: electric component; 29: charged plate; 31: ground needle; 37, 38: terminal plate; 41: substrate; 42: branch interference type optical waveguide; 42a: input/output optical waveguide; 42b, 42c: phase-shift optical waveguide; 43: buffer layer; 45: light reflecting portion; 46, 47, 48: electrode; 53a, 54a: terminal needle; 53b, 54b: metal tube

1. An optical voltage probe for measuring a voltage signal at a measurement point, the optical voltage probe comprising:
an optical modulator having modulation electrodes which include a first electrode pad and a second electrode pad, the optical modulator being configured to modulate an intensity of an incident light depending on a voltage between the first electrode pad and the second electrode pad and output the modulated incident light;
an input optical fiber and an output optical fiber that are connected with the optical modulator;
a first contact terminal and a second contact terminal that are configured to be in contact with the measurement point;
a first electric line connecting the first contact terminal with the first electrode pad;
a second electric line connecting the second contact terminal with the second electrode pad; and
a package that houses the optical modulator, at least a part of the first electric line, at least a part of the second electric line, a part of the input optical fiber and a part of the output optical fiber, wherein
the voltage signal induced between the first electrode pad and the second electrode pad via the first contact terminal and the second contact terminal is converted into an optical intensity modulation signal by the optical modulator and the optical intensity modulation signal is outputted through the output optical fiber,
the first contact terminal and the second contact terminal or the first electric line and the second electric line include a crossing portion so that the first contact terminal and the second contact terminal or the first electric line and the second electric line are crossed with each other at the crossing portion in a non-contact manner, and
when a magnetic field penetrating between the first contact terminal and the second contact terminal or between the first electric line and the second electric line varies, electromotive forces in opposite directions are induced between the first contact terminal and the second contact terminal or between the first electric line and the second electric line at portions before and after the crossing portion by the magnetic field which varies.

2. The optical voltage probe according to claim 1, wherein
the magnetic field is generated by an electric load in a test environment where the electric load is applied to an electric circuit or an electric component, and
the measurement point is located in the electric circuit or the electric component.

3. The optical voltage probe according to claim 1, wherein
the first contact terminal and the second contact terminal or the first electric line and the second electric line include a plurality of crossing portions, each of the plurality of crossing portions being the crossing portion.

4. The optical voltage probe according to claim 1, wherein
the first electric line and the second electric line are twisted together in the non-contact manner.

5. The optical voltage probe according to claim 1, wherein
the first electric line and the second electric line include the crossing portion,
a first area of a first region enclosed by a first straight line connecting terminals of the first electric line and the second electric line, the first electric line, the second electric line and the crossing portion or a second area of a second region enclosed by the crossing portion, the first electric line, the second electric line and a second straight line connecting rear ends of the first electric line and the second electric line is adjustable.

6. The optical voltage probe according to claim 1, wherein
the first electric line and the second electric line includes the crossing portion, and
lengths of the first contact terminal and the second contact terminal are adjustable so that an area of a region enclosed by a straight line connecting terminals of the first contact terminal and the second contact terminal, the first contact terminal, the second contact terminal, the first electric line and the second electric line which are connected respectively with the first contact terminal and the second contact terminal, and the crossing portion is adjustable.

7. The optical voltage probe according to claim 1, wherein
the optical modulator is a branch interference type optical modulator using an optical waveguide formed on a lithium niobate crystal substrate.

8. The optical voltage probe according to claim 1, wherein
the optical modulator is a branch interference type optical modulator using an optical waveguide formed on a lithium niobate crystal substrate,
the incident light is reflected inside the optical modulator to change a direction of the incident light, and
the input optical fiber and the output optical fiber are formed by one input/output optical fiber.
